(19) United States
(12) Patent Application Publication
(10) Pub. No.: US 2020/0363014 A1
(43) Pub. Date: Nov. 19, 2020

(54) VACUUM VESSEL

(71) Applicant: International Business Machines Corporation, Armonk, NY (US)

(72) Inventors: Sean Hart, Tarrytown, NY (US); Valerio A. Grendanin, St. Augustine, FL (US); Patryk Gumann, Tarrytown, NY (US)

(21) Appl. No.: 16/412,528

(22) Filed: May 15, 2019

(51) Int. Cl. F17C 13/00; H01F 6/04

(52) U.S. Cl. CPC F17C 13/002; H01F 6/04; F17C 2201/0119; F17C 2270/0527; F17C 2221/017; F17C 2223/0161; F17C 2250/032; F17C 2201/032

(57) ABSTRACT

A vacuum vessel supporting superconducting computing device environments includes a vacuum vessel having a cylindrical chamber defined by an internal frame, including upper and lower mounting rings, and at least two vertical support members disposed between the upper and lower mounting rings. The chamber is further defined by an upper plate releasably attached to the upper mounting ring, a lower plate releasably attached to the lower mounting plate, at least two side walls releasably attached to the upper mounting ring, the lower mounting ring and at least two vertical support members. Seal elements are disposed between the upper plate and the upper mounting ring, the lower plate and the lower mounting ring, and each side wall and the internal frame.

### BACKGROUND

The disclosure relates generally to vacuum vessels. The disclosure relates particularly to sectioned pressure vessels for high vacuum level cryogenics uses.

Superconducting apparatus, including quantum computers, can require low temperature, high vacuum environments to function properly. Containing these environments requires vessels designed to accommodate the cryogenic and vacuum systems to maintain the needed environmental conditions. Typical vacuum vessel design includes a lower can with a lid.

### SUMMARY

Aspects of the invention disclose vacuum vessels and environmental systems for a housing apparatus requiring low temperatures and high vacuum levels. In one aspect, a vacuum vessel supporting superconducting computing device environments includes a vacuum vessel having a cylindrical chamber defined by an internal frame including upper and lower mounting rings and at least two vertical support members disposed between the upper and lower mounting rings. The chamber is further defined by an upper plate releasably attached to the upper mounting ring, a lower plate releasably attached to the lower mounting ring, at least two side walls releasably attached to the upper mounting ring, the lower mounting ring and at least two vertical support members. Seal elements are disposed between the upper plate and the upper mounting ring, the lower plate and the lower mounting ring, and each side wall and the internal frame.

In one aspect, a vacuum vessel supporting a high vacuum, low temperature environment, the vacuum vessel includes at least two vessel portions, each vessel portion comprising a portion of an axially divided cylinder, each vessel portion including a part of the upper surface, lower surface and side walls of the cylinder, and a seal element disposed between a first vessel portion and a second vessel portion.

In one aspect, a vacuum vessel supporting a high vacuum, low temperature environment, the vacuum vessel includes a first vessel element, the first vessel element having an upper surface of a cylinder, a lower surface of the cylinder, and a first portion of the side wall of the cylinder. The upper surface of the cylinder, lower surface of the cylinder, and first portion of the side wall of the cylinder are fixedly joined as a single structure. The vessel also includes a second vessel element, the second vessel element having a second portion of the side wall of the cylinder, and a seal element disposed between the first element and the second element. The second element is releasably attached to the first vessel element to define a cylindrical chamber.

In one aspect, a system supporting superconducting computing includes a vacuum vessel, wherein the vacuum vessel includes a cylindrical chamber defined by an internal frame including upper and lower mounting rings and at least two vertical support members disposed between the upper and lower mounting rings, an upper plate releasably attached to the upper mounting ring, a lower plate releasably attached to the lower mounting ring, and at least two side walls, each side wall releasably attached to the upper mounting ring, the lower mounting ring and at least two vertical support members. Seal elements are disposed between the upper plate and the upper mounting ring, the lower plate and the lower mounting ring, and each side wall and the internal frame. A sealable opening is disposed upon one of: the sidewalls, upper plate, lower plate or internal frame. A vacuum system is disposed outside the vacuum vessel and operably connected to the sealable opening. A refrigeration element is disposed at least partially within the vacuum vessel, and a superconducting computation device is disposed within the vacuum vessel.

In one aspect, a system supporting superconducting computing includes a vacuum vessel having a first vessel element, the first vessel element including an upper surface of a cylinder, a lower surface of the cylinder, and a first portion of the side wall of the cylinder. The upper surface of the cylinder, lower surface of the cylinder, and first portion of the side wall of the cylinder are fixedly joined as a single structure. The vessel also includes a second vessel element having a second portion of the side wall of the cylinder, and a seal element disposed between the first element and the second element. The second element is releasably attached to the first vessel element to define a cylindrical chamber. The system also includes a refrigeration element disposed at least partially within the vacuum vessel, and a superconducting computing device disposed within the vacuum vessel.

### BRIEF DESCRIPTION OF THE DRAWINGS

FIG. 1 provides a schematic illustration of an exploded perspective view of a vessel, according to an embodiment of the invention. The vessel of the figure is exploded along brackets A and B.

FIG. 2 provides a schematic illustration of an exploded perspective view of a vessel, according to an embodiment of the invention. The vessel of the figure is exploded along bracket C.

FIG. 3 provides a schematic illustration of an exploded perspective view of a vessel, according to an embodiment of the invention. The vessel of the figure is exploded along bracket D.

FIG. 4 provides a schematic illustration of a system, according to an embodiment of the invention.

### DETAILED DESCRIPTION

Quantum computers rely upon superconducting qubit structures. Maintaining the properties of the structures requires very low temperatures (10-15 mK) and very high levels of vacuum (10⁻⁶ mBar). Advances in quantum computers require structures scaled to include large numbers (millions) of qubits. Typical implementations of small numbers of qubits are difficult to scale up due to the vertical clearance requirements of the associated vacuum vessels. Such vertical clearances can be between 0.7 and 1.5 meters required above, or below, the vacuum vessel to open the vessel and access the quantum computing, or other apparatus. What is desired is a vessel design which can support the temperature and vacuum requirements without the need for large overhead clearances.

Quantum computational systems require a vacuum vessel which can support the environment described above in terms of the temperature and vacuum needs. Such systems can include cryo pump vacuum systems to evacuate the vacuum vessel by adsorbing gases out of the space being evacuated. The temperature of the gases is lowered, and the gases are captured and removed from the space. The cryopump may be used in conjunction with other typical vacuum systems, such as external pumps, as a final step in creating the necessary high levels of vacuum in the space.

Quantum computing devices employing superconducting qubits must be maintained at very low (10-15 mK) temperatures. Cryogenic refrigeration systems can be used to maintain such temperatures. In an embodiment, dilution refrigeration systems employing a mixture of Helium isotopes can be disposed within the vacuum system and coupled to the computing system to achieve and maintain the low temperatures.

Maintenance of the apparatus requires opening the pressure vessels and accessing the apparatus. Typically, accessing the apparatus either requires removing the lid and apparatus far enough upward to clear the can or moving the can downward far enough to clear the apparatus. These steps necessitate relatively large amounts of vertical clearance above or below the vessel, and therefore systems using this design have limited scalability to larger system sizes.

In an embodiment, the overall environmental system can include one or more cranes for the purpose of articulating system components during assembly and disassembly of the system. Examples include overhead and floor mounted gantry cranes for moving vessel elements, computational elements as well as vacuum and refrigeration system components.

The disclosed vacuum vessels can include one or more sealable openings. The openings can be disposed upon the top, bottom or sides of the cylindrical vacuum vessels of the disclosure. The sealable openings can be used to connect the interior of the vacuum vessel to a vacuum system for evacuation, or to connect the portion of cryogenic refrigeration system within the vacuum vessel and coupled to the computing device to the remainder of the refrigeration system disposed outside the vacuum vessel.

In an embodiment, a vacuum vessel comprises a cylindrical internal frame which includes upper and lower mounting rings. The mounting rings comprise annular structures having an outer diameter defining the circumference of the cylinder and an inner diameter defining an opening in each mounting ring. The mounting rings are separated by two or more vertical support members along the axis of the cylinder, at or near the outer circumference of the mounting rings. In an embodiment, two support members are spaced evenly around the circumference of the cylinder. Additional support members can be included, and the total support members can be spaced evenly around the circumference of the cylinder.

Upper and lower plates are configured to be releasably attached to the upper and lower mounting rings, respectively. The plates comprise a plurality of mounting holes arranged in a circular pattern corresponding to a pattern of holes in the respective upper and lower mounting rings. The plates can comprise a pilot surface consisting of a cylindrical portion of the plate having a diameter less than the inner diameter of the corresponding mounting ring such that the pilot plate extends into the opening of the ring when the vessel is assembled. The mounting ring holes can be threaded to accept threaded fasteners passed through the holes of the plates. One or more pilot holes can be present in either the plate or the ring with corresponding pilot elements protruding from the corresponding element to ease alignment of the elements during assembly.

In an embodiment, the vessel comprises two or more side wall elements. The side wall elements are adapted to mate with the upper and lower mounting rings as well as the vertical support members. The side wall elements have internal and external surfaces, the internal surfaces combining to define a substantially cylindrical shape. The side walls comprise a plurality of mounting holes corresponding to mounting holes disposed upon the mating surfaces of the vertical support members and mounting rings. The support member and ring holes may be threaded to accept fasteners passed through the holes of the side wall elements for assembly. The internal frame, side wall combinations can comprise pilot holes and protruding pilot elements to facilitate vessel assembly. Each side wall element defines a portion of a cylinder between two corresponding vertical support members. In an embodiment having two vertical support members, two side wall elements are required. For three vertical supports, three side walls are required, and so on.

When assembled, inner surfaces of the side walls, internal frame and plates define a cylindrical vacuum vessel. The assembled vessel can be partially disassembled by removing one or more side walls, affording access to the interior of the vessel without a need for significant clearance above or below the vessel.

In an embodiment, the internal frame elements comprise sealing channels. Each sealing channel is adapted to accommodate an elastomeric seal element such as an O-ring. A first side-wall sealing channel can extend radially along a vertical surface of an outer circumference of a first portion of the upper mounting ring, continue along an axial outer surface of a vertical support member, along a vertical surface of an outer circumference of a matching portion of the lower ring, then along an axial outer surface of a second vertical support member, defining a continuous sealing surface. The transitions from the rings to the supports are defined by a radius. One or more additional side-wall sealing channels can be disposed on similar portions of the internal frame such that all portions of the vertical surfaces of the upper and lower rings between vertical support members comprise a portion of a sealing channel and all vertical support members comprise portions of two sealing channels. O-rings disposed in these side-wall sealing channels are intended to seal against corresponding surfaces of the side walls when the vessel is assembled.

In an embodiment, the side-wall sealing channels are disposed in the side wall elements. O-rings disposed in the side-wall channels are adapted to seal against the internal frame elements when the vessel is assembled.

In an embodiment, redundant sealing channels can be disposed in either the frame elements or the side walls or a combination of both the side-walls and the internal frame elements.

In an embodiment, additional sealing channels can be formed in the upper surface of the upper mounting ring and the lower surface of the lower mounting ring. These additional sealing surfaces are disposed inside the mounting hole pattern of the rings. The sealing channels can be circular. O-rings in these channels are intended to seal against the lower surface of the upper plate and the upper surface of the lower plate, respectively.

In an embodiment, O-rings are disposed between the inner diameters of the upper and lower rings and the corresponding outer surfaces of the pilot portions of the upper and lower plates. In an embodiment, sealing channels are disposed in the vertical surface of the inner diameter of the upper and lower rings. In an embodiment, the sealing channels are disposed in the outer vertical surface of the pilot portion of the upper and lower plates.

In an embodiment, a vacuum vessel supports a high vacuum, low temperature environment. The vacuum vessel includes at least two vessel portions, and each vessel portion constitutes a portion of an axially divided cylinder. The assembled portions define an inner cylindrical chamber. Each vessel portion includes a part of each the upper surface, lower surface and side walls of the cylinder. Each portion includes a mating surface corresponding to a matching mating surface of the other portion(s). Each portion can include mounting flanges extending normally from the portion at an edge defined by the mating surface. The mounting flange includes a plurality of mounting holes such that mounting fasteners, such as bolts, can be passed through the holes of at least one portion into holes of another portion. Holes of one portion can be threaded to accept the fasteners passed through the holes of another portion. In an embodiment, fasteners, such as bolts, are passed through the holes of two adjacent portions and secured in place with corresponding elements, such as nuts. The portions can comprise alignment pins, or dowels, and corresponding holes in the opposing portion to facilitate assembly of the vessel. The portions can be formed along a chord of the upper and lower surfaces of the cylinder. In an embodiment, the chord can be the diameter of the cylinder. In an embodiment, the portions can split the cylinder axially along the cylinder side wall. In an embodiment, the portions split the cylinder side wall along a conic section of the cylinder wall. In an embodiment, the mating surfaces of the portions can include a seal channel for an O-ring seal between the portions. In an embodiment, a gasket may be placed between the portions to provide a seal when the vessel is assembled.

In an embodiment, a vacuum vessel supporting a high vacuum, low temperature environment, the vacuum vessel includes a first vessel element and a second vessel element. The assembled elements define a cylindrical vacuum vessel chamber. The first vessel element includes an upper surface of a cylinder, a lower surface of the cylinder, and a first portion of the side wall of the cylinder. In an embodiment, the upper surface, lower surface and side wall portion can be fixedly joined together as a single unit. The surfaces and wall portion can be a single casting, machined to finish mating surfaces, etc. The first vessel element can be fabricated from upper, lower, and side wall components welded together to unitize the element. A composite structure can be fabricated consisting of the upper, lower and side wall portions. The lower portion of the upper surface, and upper portion of the lower surface can be defined by a radiused portion. The radius of this portion can substantially match the inner radius of the side wall portion. The radiused portions can include a plurality of threaded mounting holes configured to align with upper and lower mounting holes of the second vessel element. The second vessel element includes a second portion of the side wall of the cylinder. The assembled vessel includes the complete cylinder sidewall.

In an embodiment, the first and second vessel elements each include mounting flanges disposed along the side wall edges of the respective elements. The corresponding flanges include a plurality of aligned mounting holes enabling the assembly of the vessel by passing fasteners through the mounting holes of one element into threaded holes of the other element, or by passing fasteners through the mounting holes of both elements and securing the fasteners.

In an embodiment, the vessel is assembled by aligning the first and second elements and passing mounting fasteners through mounting holes of the second element into threaded holes of the radiused portions of the first element together with using fasteners in conjunction with the mounting holes of the flanges of the elements.

In an embodiment, at least one seal element is disposed between the first element and the second element. The at least one seal element can include a sealing channel adapted to receive an elastomeric seal, such as an O-ring. The sealing channel can be disposed upon either the first or second vessel element. Redundant sealing channels and corresponding O-rings seals can be used. In an embodiment, a gasket seal is disposed between the first and second element of the vessel.

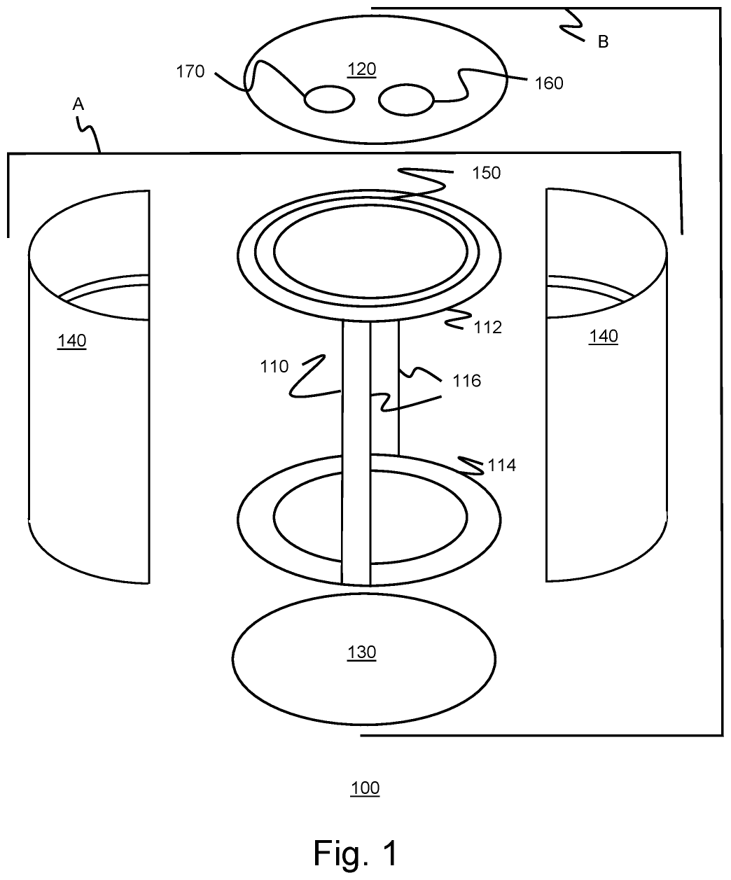

FIG. 1 provides an exploded schematic perspective view of a vacuum vessel 100, according to an embodiment of the invention. As shown in the figure, internal frame 110 includes upper mounting ring 112, lower mounting ring 114, and vertical support elements 116. Upper ring 112 comprises a sealing element 150. Additional sealing elements (not shown) can be disposed along surfaces of the upper and lower rings, together with vertical surfaces of the vertical support elements 116. Lower ring 114 can also comprise a sealing element. Upper plate 120 and lower plate 130 are assembled to internal frame 110 as indicated by bracket B. Side walls 140 are assembled to internal frame 110 as indicated by bracket A. The vessel 100 also comprises one or more ports 160, permitting transmission of electromagnetic signals. The electromagnetic signals may comprise a plurality of DC signals, microwave signals, or electromagnetic radiation. Vessel 100 also comprises one or more sealable openings 170. Sealable openings can be used for evacuation of the vessel, for enabling access between the vessel interior and the external environment for refrigeration, or for other utilities.

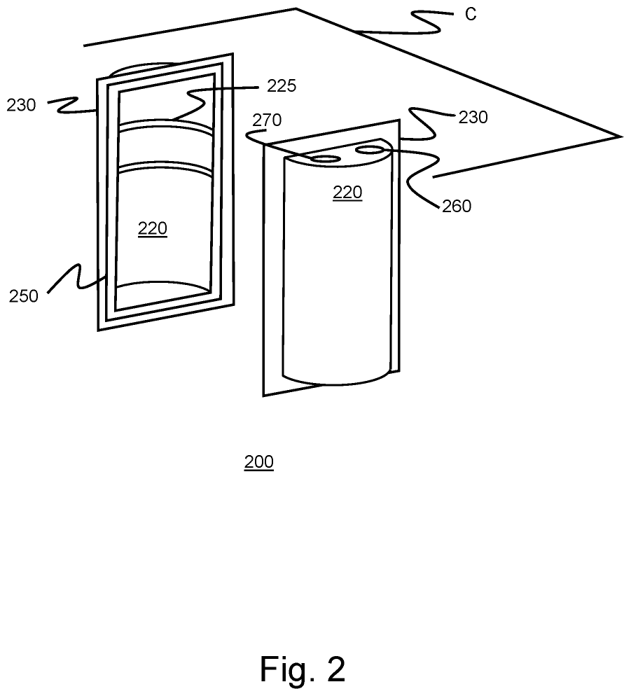

FIG. 2 provides an exploded schematic perspective view of a vacuum vessel 200, according to an embodiment of the invention. As shown in the figure, vessel elements 220 are assembled according to bracket C. The vessel elements 220 comprise mounting flanges 230. Sealing element 250 is disposed between vessel elements 220. Vessel elements 220 can comprise one or more internal reinforcing ribs 225. Vessel 200 also comprises one or more ports 260, permitting transmission of electromagnetic signals. The electromagnetic signals may comprise a plurality of DC signals, microwave signals, or electromagnetic radiation. Vessel 200 also comprises one or more sealable openings 270. Sealable openings can be used for evacuation of the vessel, for enabling access between the vessel interior and the external environment for refrigeration, or for other utilities.

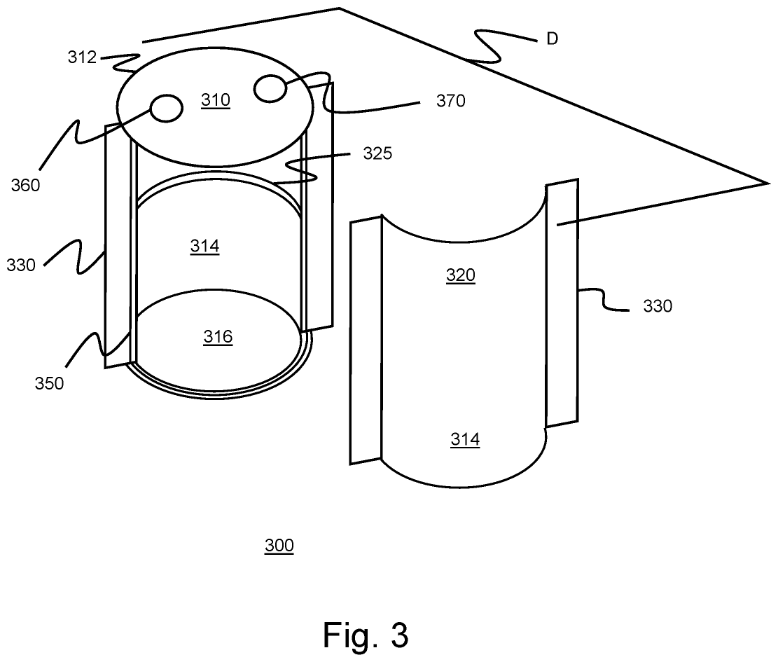

FIG. 3 provides an exploded schematic perspective view of a vacuum vessel 300, according to an embodiment of the invention. As shown in the figure, vessel portion 310 includes an upper surface 312, side wall portion 314, and lower surface 316, of a cylinder. Vessel portion 320 includes a second side wall portion 314, of the cylinder. First and second vessel portions 310, 320 are assembled according to bracket D of the figure. Each of the vessel portions 310 and 320 comprise mounting flanges 330 to facilitate fastening the portion to form vacuum vessel 300. The vessel portions 310, 320 comprise reinforcing ribs 325. Seal element 350 is disposed on a mating surface of the vessel elements 310, 320, mounting flanges 330. Vessel 300 also comprises one or more ports 360, permitting transmission of electromagnetic signals. The electromagnetic signals may comprise a plurality of DC signals, microwave signals, or electromagnetic radiation. Vessel 300 also comprises one or more sealable openings 370. Sealable openings can be used for evacuation of the vessel, for enabling access between the vessel interior and the external environment for refrigeration, or for other utilities.

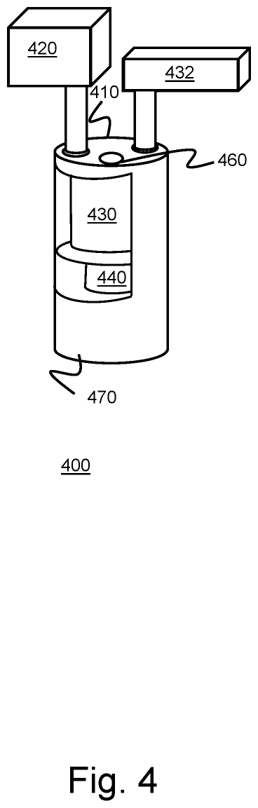

FIG. 4 provides a schematic illustration of a system 400, according to an embodiment of the invention. As provided in the figure, system 400 comprises vacuum vessel 410. For purposes of illustration a portion of the side wall of vacuum vessel 410 is shown cut away in the figure. System 400 further includes vacuum element 420 coupled to the interior of vacuum vessel 410 via sealable opening 470. A refrigeration system includes a refrigeration element 430 disposed inside vacuum vessel 410 and a portion 432 disposed outside vacuum vessel 410. Superconducting computation element 440 is disposed inside vacuum vessel 410. In an embodiment, superconducting computation element 440 is thermally coupled to refrigeration element 430. Vessel 410 also comprises a port 460, permitting transmission of electromagnetic radiation through the walls of vessel 410.

The disclosed vacuum vessel structures may be fabricated from aluminum alloy, stainless steel, other suitable metals, composite materials and combinations of these materials. Portions of the vessel can be fabricated from materials transparent to electromagnetic radiation. Such portions can constitute a data port where signals can be passed between the inside of the vessel and the outside of the vessel. Materials for such a port include: fiberglass or silicon dioxide. The elements can be fabricated using known techniques including casting, machining, forming, welding, composite fabrication, etc.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the Figures. The terms “overlying”, “atop”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A vacuum vessel comprising:
a cylindrical chamber defined by:
an internal frame including an upper mounting ring and a lower mounting ring, and at least two vertical support members disposed between the upper and lower mounting rings;
an upper plate releasably attached to the upper mounting ring;
a lower plate releasably attached to the lower mounting ring;
at least two side walls, each side wall releasably attached to the upper mounting ring, the lower mounting ring, and at least two vertical support members; and
a seal element disposed between at least one of: the upper plate and the upper mounting ring, the lower plate and the lower mounting ring, and each side wall and the internal frame.

2. The vacuum vessel according to claim 1, further comprising one or more ports permitting transmission of a plurality of DC signals, microwave signals, or electromagnetic radiation, wherein the port is disposed upon one of: the side walls, the upper plate, or the lower plate.

3. The vacuum vessel according to claim 1, wherein at least one seal element comprises an O-ring seal.

4. The vacuum vessel according to claim 1, further comprising one or more sealable openings, the sealable openings disposed upon one of the side walls, upper plate, or lower plate.

5. The vacuum vessel according to claim 4, a vacuum system adapted to evacuate the vacuum vessel through a sealable opening.

6. The vacuum vessel according to claim 1, further comprising a refrigeration element disposed at least partially within the vacuum vessel.

7. The vacuum vessel according to claim 1, further comprising a computation device disposed within the vacuum vessel.

8. A vacuum vessel supporting a high vacuum, low temperature environment, the vacuum vessel comprising:
at least two vessel portions, each vessel portion comprising a portion of an axially divided cylinder, each vessel portion including a part of an upper surface, lower surface and side walls of the cylinder; and
a seal element disposed between a first vessel portion and a second vessel portion;
wherein each portion comprises a mating edge and a mounting flange disposed adjacent to the mating edge.

9. The vacuum vessel according to claim 8, wherein the seal element comprises an O-ring seal.

10. The vacuum vessel according to claim 8, further comprising one or more ports permitting transmission of a plurality of DC signals, microwave signals, or electromagnetic radiation, the port disposed upon one of: the upper surface, the lower surface, or the side walls.

11. The vacuum vessel according to claim 8, further comprising sealable openings disposed upon one of: the upper surface, the lower surface, or the side walls.

12. The vacuum vessel according to claim 11, further comprising a vacuum system disposed outside the vacuum vessel and adapted to evacuate the vacuum vessel through a sealable opening.

13. The vacuum vessel according to claim 8, further comprising a refrigeration element disposed at least partially within the vacuum vessel.

14. The vacuum vessel according to claim 8, further comprising a computation device disposed within the vacuum vessel.

15. A vacuum vessel supporting a high vacuum, low temperature environment, the vacuum vessel comprising:
a first vessel element, the first vessel element including:
an upper surface of a cylinder;
a lower surface of the cylinder;
a first portion of a side wall of the cylinder; and
a second vessel element, the second vessel element including:
a second portion of the side wall of the cylinder; and
a seal element disposed between the first vessel element and the second vessel element;
wherein the upper surface of the cylinder, the lower surface of the cylinder, and first portion of the side wall of the cylinder of the first vessel element, are fixedly joined as a single structure;
wherein the second vessel element is releasably attached to the first vessel element to define a cylindrical chamber.

16. The vacuum vessel according to claim 15, wherein the seal element comprises an O-ring seal.

17. The vacuum vessel according to claim 15, further comprising one or more ports permitting transmission of a plurality of DC signals, microwave signals, or electromagnetic radiation, disposed on one of: the upper surface, the lower surface and the side walls of the cylinder.

18. The vacuum vessel according to claim 15, further comprising sealable openings disposed upon the first vessel element or the second vessel element.

19. The vacuum vessel according to claim 18, further comprising a vacuum system disposed outside the vacuum vessel and adapted to evacuate the vacuum vessel through a sealable opening.

20. The vacuum vessel according to claim 15, further comprising a refrigeration element disposed at least partially within the vacuum vessel.
